(19) United States
(12) Patent Application Publication
(10) Pub. No.: US 2026/0226609 A1
(43) Pub. Date: Aug. 6, 2026

(54) SUBSTRATE PROCESSING METHOD, SUBSTRATE PROCESSING APPARATUS, AND SUBSTRATE PROCESSING SYSTEM

(71) Applicant: Tokyo Electron Limited, Tokyo (JP)

(72) Inventors: Naoko SUZUKI, Yamanashi (JP); Miyako KANEKO, Yamanashi (JP); Tadashi MITSUNARI, Yamanashi (JP); Yasuhiro HAMADA, Yamanashi (JP); Yuutaro KISHI, Yamanashi (JP)

(21) Appl. No.: 19/451,115

(22) Filed: Jan. 16, 2026

(30) Foreign Application Priority Data
Jan. 31, 2025 (JP) 2025-015009

(51) Int. Cl. C23C 16/04; C23C 16/26; C23C 16/50; C23C 16/52

(52) U.S. Cl. CPC C23C 16/04; C23C 16/26; C23C 16/50; C23C 16/52

(57) ABSTRACT

A substrate processing method includes providing a substrate including a patterned base film; exposing the substrate to a plasma generated from a first gas containing a modifying gas, thereby hydrophobizing a surface of the patterned base film, the surface including a top of the patterned base film; and exposing the substrate to a plasma generated from a second gas containing a raw material gas containing carbon and hydrogen, thereby selectively forming a carbon film over the hydrophobized top.

### CROSS-REFERENCE TO RELATED APPLICATIONS

This application is based upon and claims priority to Japanese Patent Application No. 2025-015009, filed on Jan. 31, 2025, the entire contents of which are incorporated herein by reference.

### BACKGROUND

### 1. Field of the Invention

The present disclosure relates to a substrate processing method, a substrate processing apparatus, and a substrate processing system.

### 2. Description of the Related Art

PCT Japanese Translation Patent Publication No. 2022-539699 discloses a technique of etching a base layer using a patterned carbon film as a mask, then forming an additional carbon film over the carbon film to form a thickened carbon film, and then additionally etching the base layer using the thickened carbon film as a mask.

### SUMMARY

A substrate processing method according to an aspect of the present disclosure includes: providing a substrate including a patterned base film; exposing the substrate to a plasma generated from a first gas containing a modifying gas, thereby hydrophobizing a surface of the patterned base film, the surface including a top of the patterned base film; and exposing the substrate to a plasma generated from a second gas containing a raw material gas containing carbon and hydrogen, thereby selectively forming a carbon film over the hydrophobized top.

### BRIEF DESCRIPTION OF THE DRAWINGS

FIG. 1 is a flowchart illustrating a substrate processing method according to an embodiment of the present disclosure.

FIG. 2 is a cross-sectional diagram (1) illustrating the substrate processing method according to the embodiment.

FIG. 3 is a cross-sectional diagram (2) illustrating the substrate processing method according to the embodiment.

FIG. 4 is a cross-sectional diagram (3) illustrating the substrate processing method according to the embodiment.

FIG. 5 is a cross-sectional diagram (4) illustrating the substrate processing method according to the embodiment.

FIG. 6 is a diagram (1) illustrating a conventional substrate processing method.

FIG. 7 is a diagram (2) illustrating the conventional substrate processing method.

FIG. 8 is a diagram (3) illustrating the conventional substrate processing method.

FIG. 9 is a diagram (4) illustrating the conventional substrate processing method.

FIG. 10 is a diagram (5) illustrating the conventional substrate processing method.

FIG. 11 is a diagram (6) illustrating the conventional substrate processing method.

FIG. 12 is a diagram illustrating a substrate processing system according to an embodiment of the present disclosure.

FIG. 13 is a schematic cross-sectional diagram illustrating a substrate processing apparatus according to an embodiment of the present disclosure.

FIG. 14 is a table illustrating results obtained by observing cross sections of carbon films.

FIG. 15 is a table illustrating results obtained by measuring water contact angles of sample surfaces.

### DETAILED DESCRIPTION OF THE DISCLOSURE

The present disclosure provides a technique that can reduce defects in a root portion of a carbon film when forming the carbon film over a top of a patterned base film.

Hereinafter, non-limiting embodiments of the present disclosure will be described with reference to the drawings. In the drawings, the same or corresponding members or components are denoted by the same or corresponding reference signs, and duplicate description thereof will be omitted.

### Substrate Processing Method

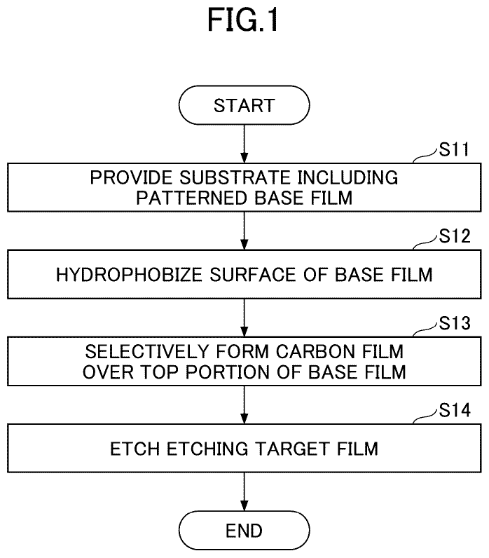

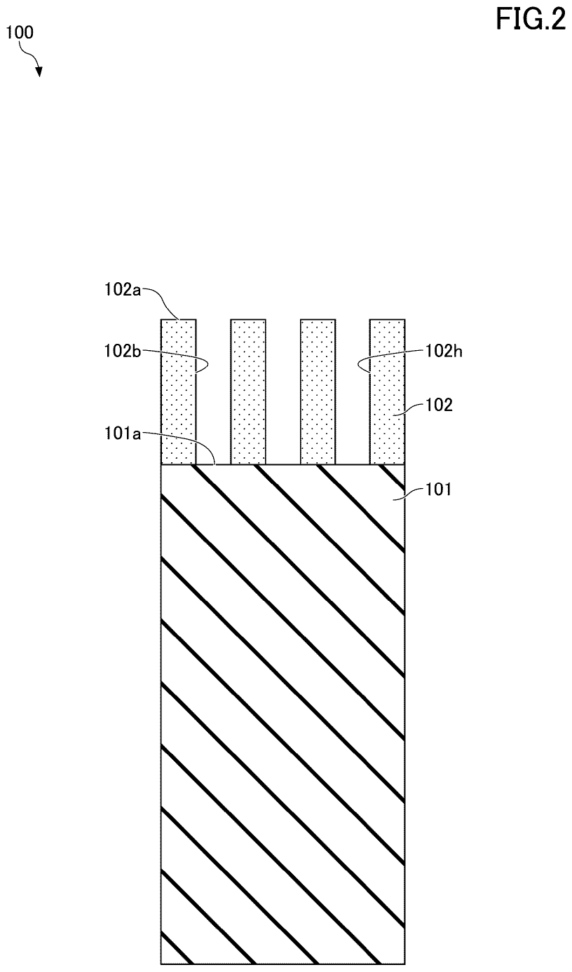

FIG. 1 is a flowchart illustrating the substrate processing method according to an embodiment of the present disclosure. FIGS. 2 to 5 are cross-sectional diagrams illustrating the substrate processing method according to the embodiment. The substrate processing method according to the embodiment includes steps S11 to S14 illustrated in FIG. 1.

In step S11, a substrate 100 illustrated in FIG. 2 is provided. The substrate 100 includes an etching target film 101 and a base film 102. The etching target film 101 is, for example, a laminated film including silicon nitride films and silicon oxide films that are alternately laminated. The base film 102 is formed over the etching target film 101. The base film 102 is patterned. The base film 102 includes tops 102a and side portions 102b. The base film 102 includes through holes 102h. The side portions 102b form an inner surface of each of the through holes 102h. The etching target film 101 includes exposed surfaces 101a. Each of the exposed surfaces 101a is exposed from the base film 102 through a corresponding one of the through holes 102h. The base film 102 is, for example, a film containing silicon (Si) and oxygen (O). Examples of the film containing silicon and oxygen include a silicon oxide film, a silicon oxynitride film, and the like. The base film 102 may be, for example, an amorphous carbon film.

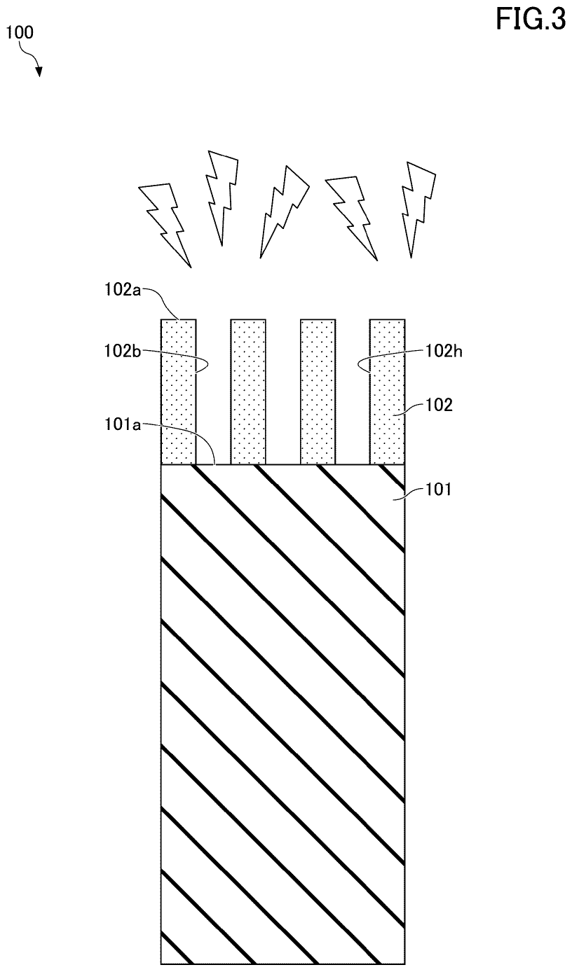

In step S12, as illustrated in FIG. 3, the substrate 100 is exposed to a plasma generated from a first gas containing a modifying gas, thereby hydrophobizing a surface of the base film 102, the surface including the tops 102a. The plasma can be generated, for example, by supplying high-frequency power to the first gas. The water contact angle of the surface of the base film 102 after the tops 102 a are hydrophobized is preferably 60 degrees (°) or more, and more preferably 90° or more. In step S12, the surface of the base film 102 including the tops 102a can be hydrophobized, for example, using a gas containing carbon (C) and halogen as the modifying gas. The gas containing carbon and halogen is, for example, a fluorocarbon gas, a hydrofluorocarbon gas, or a combination of the fluorocarbon gas and the hydrofluorocarbon gas. Examples of the fluorocarbon gas include a CF₄ gas, a C₂F₄ gas, a C₂F₆ gas, a C₃F₈ gas, a C₄F₈ gas, and a C₅F₈ gas. Examples of the hydrofluorocarbon gas include a CHF₃ gas. The first gas may include an oxygen (O₂) gas. Alternatively, by using an inert gas as the modifying gas in step S12, the surface of the base film 102 including the tops 102a can be hydrophobized. Examples of the inert gas include a helium (He) gas, an argon (Ar) gas, a xenon (Xe) gas, and the like.

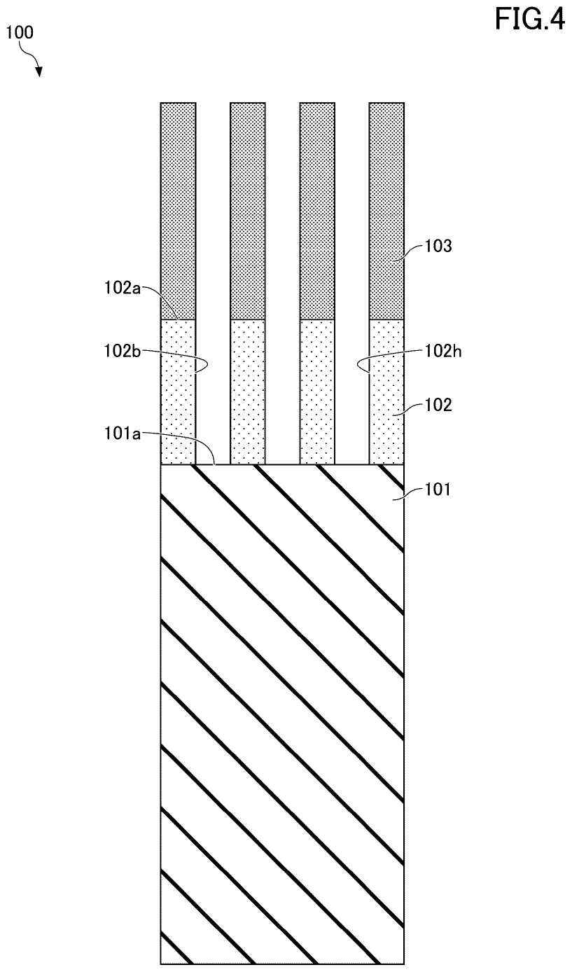

In step S13, as illustrated in FIG. 4, a carbon film 103 is formed over the tops 102a selectively relative to the side portions 102b of the base film 102. In step S13, for example, high-frequency power is supplied to generate a plasma from a second gas containing a propylene gas, a helium gas, and a hydrogen gas, and the generated plasma is supplied to the substrate 100. This causes a film-forming reaction due to carbon-based film-forming species in the plasma and an etching reaction due to reactive hydrogen species in the plasma. Since the carbon-based film-forming species have a high adhesion coefficient, the carbon-based film-forming species tend to adhere to the tops 102a rather than the side portions 102b. Since the reactive hydrogen species have a low adhesion coefficient, the reactive hydrogen species tend to reach and stay in the interior of the through holes 102h. Therefore, a film-forming reaction tends to occur on the tops 102a, and an etching reaction tends to occur on the side portions 102b. As a result, the carbon film 103 can be formed over the tops 102a of the base film 102 selectively relative to the side surfaces 102b of the base film 102. At the time step S13 is started, the surface of the base film 102 including the tops 102a is already hydrophobized. The carbon film 103 exhibits high adhesion when formed over a hydrophobized surface. This increases the adhesion between the carbon film 103, formed over the tops 102a of the base film 102, and the base film 102. As a result, even if the carbon film 103 is exposed to the reactive hydrogen species in the plasma generated from the second gas, it is possible to reduce defects, which would otherwise occur starting from the interface between the base film 102 and the carbon film 103, in root portions of the carbon film 103 that are formed in the initial stage of the film formation. A propylene gas is an example of the raw material gas containing carbon and hydrogen (H). The raw material gas may be a hydrocarbon gas other than the propylene gas, e.g., an ethylene gas or an acetylene gas. A helium gas is an example of an inert gas. The inert gas may be a noble gas other than the helium gas, e.g., an argon gas, a neon gas, or a krypton gas. The inert gas may be a nitrogen gas. The temperature of the substrate 100 in the formation of the carbon film 103 may be higher than the temperature of the substrate 100 in the hydrophobization of the surface of the base film 102 including the tops 102a.

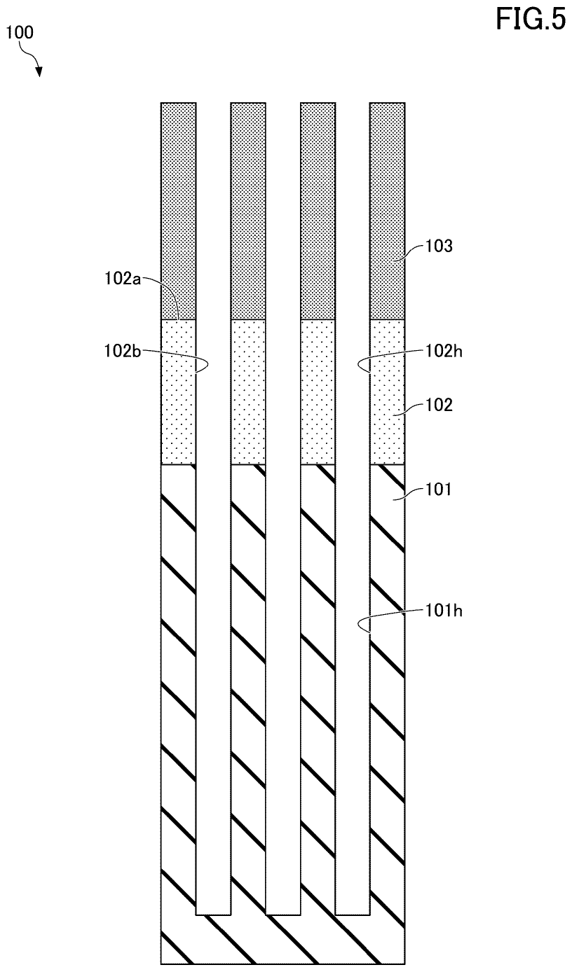

In step S14, as illustrated in FIG. 5, the etching target film 101 is etched using, as masks, the base film 102 and the carbon film 103. Thus, holes 101h are formed in the etching target film 101. For example, an etching gas that can etch the etching target film 101 selectively relative to the base film 102 and the carbon film 103 is supplied to the substrate 100. Thus, the etching target film 101 can be etched to form the holes 101h. For example, when the etching target film 101 is a laminated film including silicon nitride films and silicon oxide films alternately laminated, for example, a gas containing fluorine (F) and carbon (e.g., CₓF_{y} or CₓF_{y}H_{z}, where each of x, y, and z is an integer of 1 or greater) can be used as the etching gas. In step S14, the plasma may be generated from the etching gas.

Thus, the holes 101h can be formed in the etching target film 101.

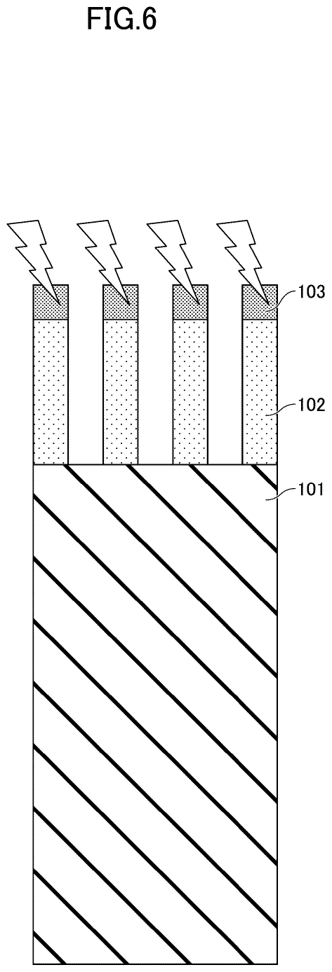

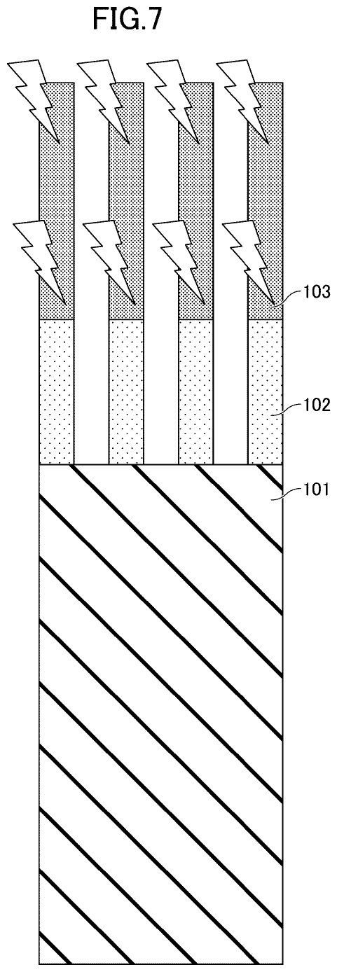

FIGS. 6 to 11 are diagrams illustrating the conventional substrate processing method. Forming the carbon film 103 by supply, to the substrate 100, of the plasma generated from the second gas containing the raw material gas containing carbon and hydrogen causes a film-forming reaction due to the carbon-based film forming species in the plasma and an etching reaction due to the reactive hydrogen species in the plasma. The carbon-based film forming species have a high adhesion coefficient, and the reactive hydrogen species have a low adhesion coefficient. Therefore, when the carbon film 103 having a large film thickness is to be formed, the carbon film 103 formed in an initial stage of the film formation is exposed to the reactive hydrogen species in the initial stage of the film formation as illustrated in FIG. 6, and is continuously exposed to the reactive hydrogen species during the film formation as illustrated in FIG. 7. In other words, when the carbon film 103 having a large film thickness is to be formed, the carbon film 103 formed in the initial stage of the film formation is exposed to the reactive hydrogen species over a long period of time. The large film thickness is, for example, 300 nanometers (nm) or greater.

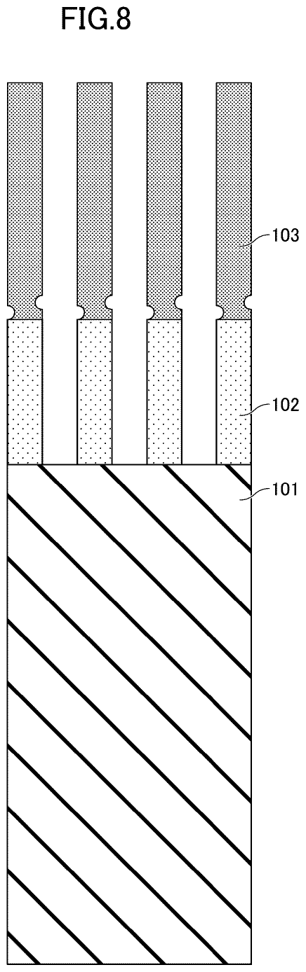

Here, considering the case in which adhesion is low between the base film 102 and the carbon film 103, defects occurring starting from the interface between the base film 102 and the carbon film 103 are formed in the root portions of the carbon film 103 that are formed in the initial stage of the film formation. This is likely because low adhesion between the base film 102 and the carbon film 103 leads to low etching resistance at the interface between the base film 102 and the carbon film 103. As a result, as illustrated in FIG. 8, the root portion of the carbon film 103 may be thinned.

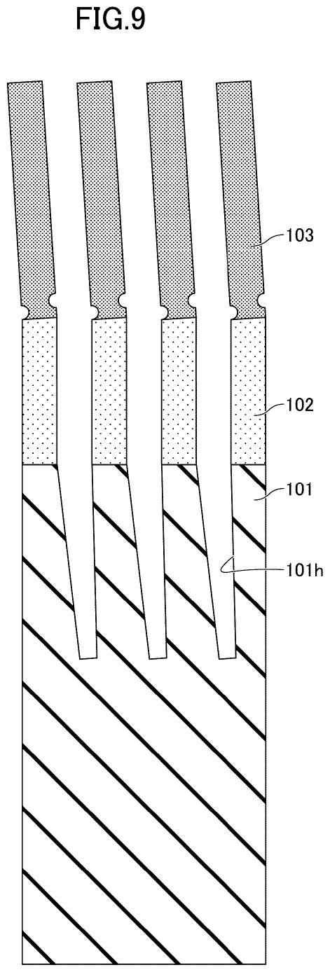

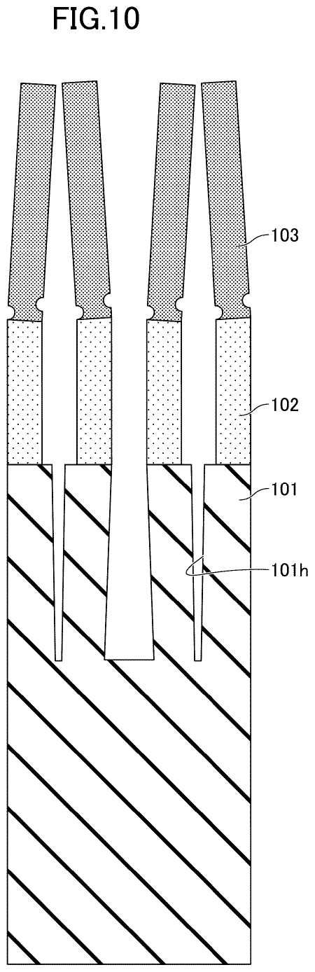

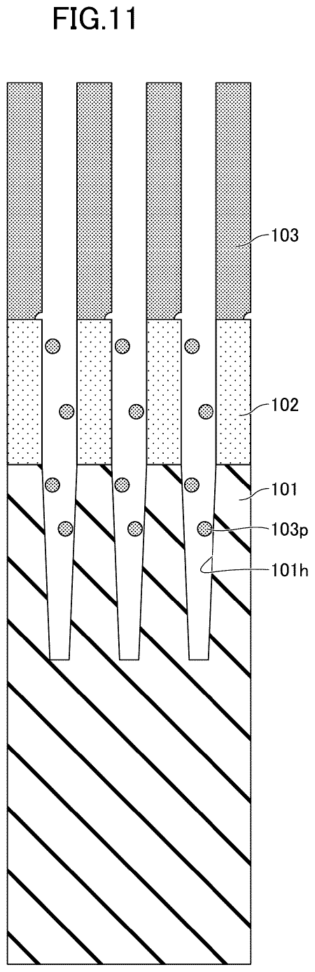

When the etching target film 101 is etched using, as a mask, the carbon film 103 having a thinned root portion, the carbon film 103 becomes tilted, as illustrated in FIG. 9, resulting in poor etching straightness of the etching target film 101. Also, as illustrated in FIG. 10, the carbon film 103 collapses, resulting in a decreased or increased opening diameter of the holes 101h formed in the etching target film 101. Also, the root portion of the carbon film 103 is fragile, and thus crumbles apart during etching, resulting in the formation of particles 103p, as illustrated in FIG. 11.

According to the substrate processing method according to the embodiment, first, in step S12, the substrate 100 is exposed to the plasma generated from the first gas containing a modifying gas, thereby hydrophobizing the surface of the base film 102 including the tops 102a. Next, in step S13, the substrate 100 is exposed to the plasma generated from the second gas containing the raw material gas containing carbon and hydrogen, thereby selectively forming the carbon film 103 over the hydrophobized tops 102a. In this case, at the time step S13 is started, the surface of the base film 102 including the tops 102a is already hydrophobized. The carbon film 103 has high adhesion when formed over the hydrophobized surface. This increases adhesion between the carbon film 103, formed over the tops 102a of the base film 102, and the base film 102. As a result, even if the carbon film 103 is exposed to the reactive hydrogen species in the plasma generated from the second gas, it is possible to reduce defects, which would otherwise occur starting from the interface between the base film 102 and the carbon film 103, in root portions of the carbon film 103 that are formed in the initial stage of the film formation. In other words, it is possible to reduce defects in the root portions of the carbon film 103 when forming the carbon film 103 over the tops 102a of the patterned base film 102.

### Substrate Processing System

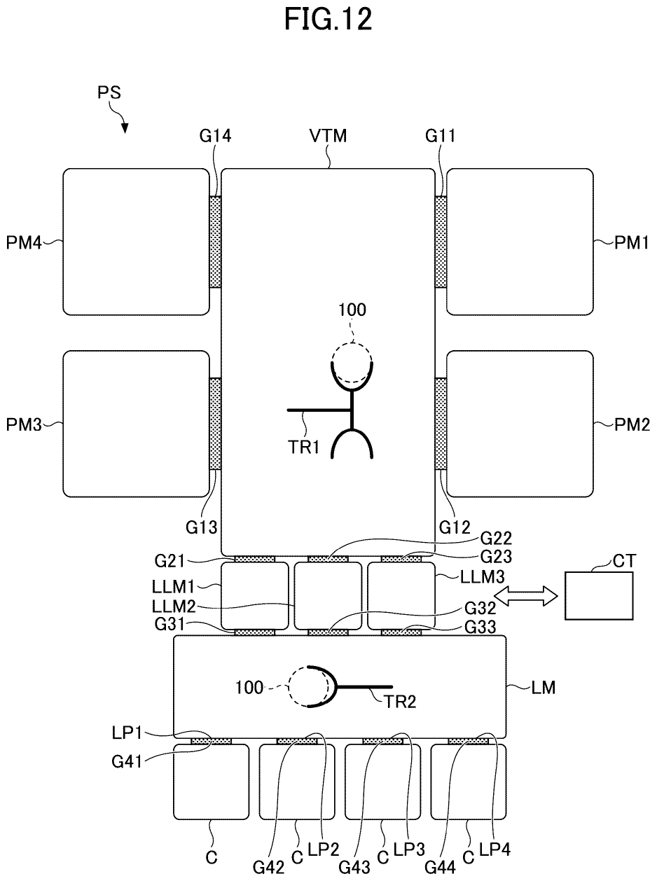

FIG. 12 is a diagram illustrating a substrate processing system PS according to an embodiment of the present disclosure. In the following description, the substrate processing system PS includes four processors PM1 to PM4. However, the number of processors is not limited to four. The number of load lock chambers and the number of load ports are not limited to the numbers illustrated in FIG. 12.

The substrate processing system PS includes the processors PM1 to PM4, a vacuum transfer chamber VTM, load lock chambers LLM1 to LLM3, an atmospheric transfer chamber LM, load ports LP1 to LP4, and a controller CT.

The processors PM1 to PM4 are connected to the vacuum transfer chamber VTM via gate valves G11 to G14. The interior of the processors PM1 to PM4 is reduced in pressure to a predetermined vacuum atmosphere, and desired processing is performed on the substrate 100 in the interior of the processors PM1 to PM4. The desired processing includes steps S12 and S13 in the above-described substrate processing method.

The vacuum transfer chamber VTM is reduced in pressure to a predetermined vacuum atmosphere. The vacuum transfer chamber VTM is provided with a transfer mechanism TR1 configured to transfer the substrate 100 under reduced pressure. The transfer mechanism TR1 transfers the substrate 100 to the processors PM1 to PM4 and the load lock chambers LLM1 to LLM3. The transfer mechanism TR1 includes, for example, two transfer arms. The transfer mechanism TR1 may include a single arm.

The load lock chambers LLM1 to LLM3 are connected to the vacuum transfer chamber VTM via gate valves G21 to G23, and are connected to the atmospheric transfer chamber LM via gate valves G31 to G33. The load lock chambers LLM1 to LLM3 are switched between an atmospheric atmosphere and a vacuum atmosphere.

The interior of the atmospheric transfer chamber LM is an atmospheric atmosphere and, for example, a downflow of clean air is formed. An aligner (not shown) configured to align the substrate 100 may be provided in the interior of the atmospheric transfer chamber LM. A transfer mechanism TR2 is provided in the atmospheric transfer chamber LM. The transfer mechanism TR2 includes, for example, a single transfer arm. However, the transfer mechanism TR2 may include two or more transfer arms. The transfer mechanism TR2 is configured to transfer the substrate 100 to the load lock chambers LLM1 to LLM3, carriers C of the load ports LP1 to LP4, and the aligner.

The load ports LP1 to LP4 are provided in the longitudinal side wall of the atmospheric transfer chamber LM. The carriers C are attached to the load ports LP1 to LP4 via gate valves G41 to G44. The carrier C is, for example, a FOUP (Front Opening Unified Pod).

The controller CT is configured to control each component of the substrate processing system PS. For example, the controller CT executes operations of the processors PM1 to PM4, operations of the transfer mechanisms TR1 and TR2, opening and closing of the gate valves G11 to G14, G21 to G23, G31 to G33, and G41 to G44, and switching of the atmosphere in the load lock chambers LLM1 to LLM3.

The substrate processing system PS includes the processors PM1 to PM4, the vacuum transfer chamber VTM configured to vacuum-transfer the substrate 100 between the processors PM1 to PM4, and the controller CT. The controller CT controls the processing performed by each of the processors PM1 to PM4. In this case, when each of the processors PM1 to PM4 performs processing on the substrate 100, the processing can be performed without exposing the substrate 100 to the atmosphere, i.e., without breaking the vacuum state.

The etching of the etching target film 101 (step S14 in FIG. 1) may be performed by at least one of the processors PM1 to PM4, or may be performed by a processor that is not included in the substrate processing system PS.

Also, steps S12 and S13 illustrated in FIG. 1 may be performed by the same processor among the processors PM1 to PM4, or may be performed by different processors among the processors PM1 to PM4.

### Substrate Processing Apparatus

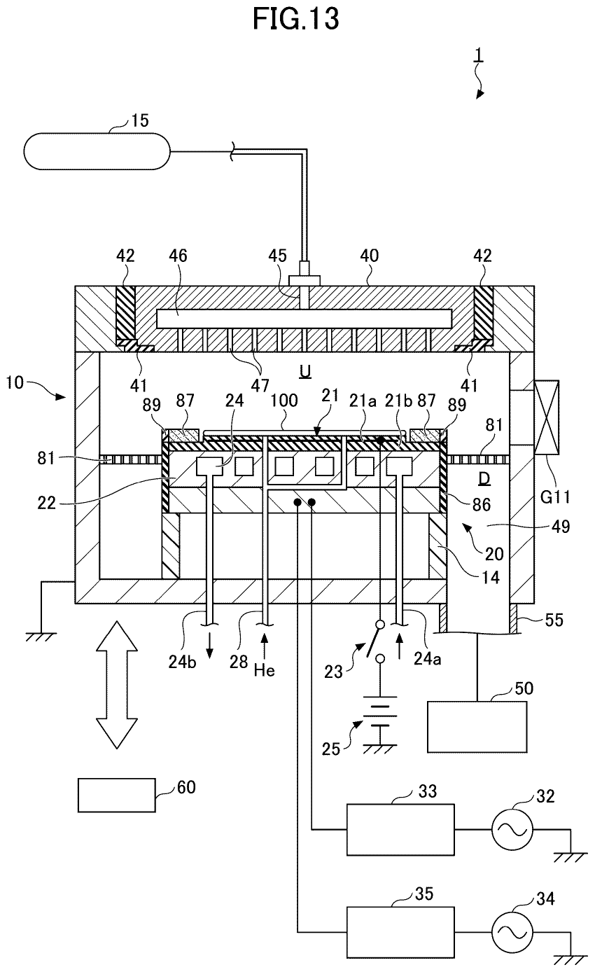

FIG. 13 is a schematic cross-sectional diagram illustrating a substrate processing apparatus 1 according to an embodiment of the present disclosure. The substrate processing apparatus 1 is applicable, for example, as the processor PM1 included in the substrate processing system PS. The substrate processing apparatus 1 is also applicable as the processors PM2 to PM4 included in the substrate processing system PS.

The substrate processing apparatus 1 is a parallel-plate plasma processing apparatus of capacitively coupled plasma (CCP).

The substrate processing apparatus 1 includes a processing chamber 10 having a substantially cylindrical shape. The inner surface of the processing chamber 10 is subjected to an anodizing treatment (anodic oxidation treatment). In the processing chamber 10, plasma processing, such as plasma etching, plasma film formation, or the like, is performed on the substrate 100.

A stage 20 includes a base 22 and an electrostatic chuck 21. The substrate 100 is placed over the upper surface of the electrostatic chuck 21. The base 22 is formed, for example, of aluminum (Al), titanium (Ti), silicon carbide (SiC), or the like.

The electrostatic chuck 21 is provided over the base 22. The electrostatic chuck 21 has a structure in which an electrode film 21a is sandwiched between insulators 21b. A DC power supply 25 is connected to the electrode film 21a via a switch 23. In a state in which the switch 23 is on, when a DC voltage is applied from the DC power supply 25 to the electrode film 21a, the substrate 100 is electrostatically attracted to the electrostatic chuck 21 due to a Coulomb force.

An annular edge ring 87 enclosing the substrate 100 is placed around the substrate 100. The edge ring 87 is formed, for example, of silicon. The edge ring 87 concentrates the plasma toward the surface of the substrate 100 in the processing chamber 10 to improve the efficiency of plasma processing.

The stage 20 is supported at the bottom of the processing chamber 10 by a support 14. A flow path 24 for passage of a coolant is formed in the interior of the base 22. The coolant output from a chiller flows and circulates through a coolant inlet tube 24a, the flow path 24, a coolant outlet tube 24b, and the chiller in this order. The circulating coolant removes heat from the stage 20, i.e., cools the stage 20. The coolant may be a liquid or gas. Examples of the coolant include cooling water and brine.

A heat transfer gas, such as a helium gas, an argon gas, or the like, supplied from a heat transfer gas supply passes through a gas supply line 28, and is supplied between the upper surface of the electrostatic chuck 21 and the rear surface of the substrate 100. With this configuration, the coolant circulating through the flow path 24 and the heat transfer gas supplied to the rear surface of the substrate 100 control the substrate 100 to a predetermined temperature.

A first high-frequency power supply 32 is connected to the stage 20 via a first matcher 33. The first high-frequency power supply 32 is configured to apply, to the stage 20, a high-frequency power HF (e.g., 40 MHz to 100 MHz) for generating a plasma of a first frequency. A second high-frequency power supply 34 is connected to the stage 20 via a second matcher 35. The second high-frequency power supply 34 is configured to apply, to the stage 20, a high-frequency power LF (e.g. 400 kHz to 2 MHz) for generating a bias voltage of a second frequency lower than the first frequency. The stage 20 also functions as a lower electrode. In the present embodiment, the high-frequency power HF for generating a plasma is applied to the stage 20, but may be applied to a shower head 40.

The first matcher 33 is configured to match an output impedance of the first high-frequency power supply 32 with a load impedance on the plasma side. The second matcher 35 is configured to match an internal impedance of the second high-frequency power supply 34 with the load impedance on the plasma side.

The shower head 40 is attached to the ceiling of the processing chamber 10, and closes the ceiling via a cylindrical shield ring 42 provided at the outer circumference of the shower head 40. The shower head 40 may be formed of silicon. The shower head 40 also functions as a counter electrode (upper electrode) facing the stage 20 (lower electrode). A top shield ring 41 formed of quartz (SiO₂) or the like is disposed over the lower surface of the shield ring 42 in a circumferential portion of the shower head 40.

A cover ring 89 and an insulator ring 86 each having an annular shape are disposed over the side surface of the stage 20 and around the edge ring 87. The cover ring 89 and the insulator ring 86 may be formed of quartz.

A gas inlet 45 is formed in the shower head 40. A diffusion chamber 46 is provided inside the shower head 40. A gas output from a gas supply source 15 is supplied to the diffusion chamber 46 via the gas inlet 45, and diffused and supplied to a plasma processing space U in the processing chamber 10 through a large number of gas supply holes 47.

A gas exhaust port 55 is formed in the bottom surface of the processing chamber 10. The interior of the processing chamber 10 is evacuated and reduced in pressure by a gas exhauster 50 connected to the gas exhaust port 55. This can maintain the interior of the processing chamber 10 at a predetermined degree of vacuum. A gate valve G11 is provided over the side wall of the processing chamber 10. The gate valve G11 is configured to be opened and closed when the substrate 100 is transferred in and out of the processing chamber 10.

An annular baffle plate 81 is attached to an upper portion of a gas exhaust path 49 formed above the gas exhaust port 55. The baffle plate 81 partitions the plasma processing space U and a gas exhaust space D, and rectifies the gas.

The substrate processing apparatus 1 includes a controller 60. The controller 60 is an electronic circuit or circuitry (including a processor), such as a central processing unit (CPU), a field programmable gate array (FPGA), an application specific integrated circuit (ASIC), or the like. The controller 60 or the controller CT is configured to execute various controls described in the present specification by executing instruction codes stored in a memory or by being designed as a circuit for specific applications.

### Operation of Substrate Processing Apparatus

Operation of the substrate processing apparatus 1 will be described when the substrate processing apparatus 1 performs steps S12 and S13 of the substrate processing method according to the embodiment.

First, opening/closing of the gate valve G11 is controlled, and the substrate 100 is transferred into the processing chamber 10. Then, the substrate 100 is placed over the stage 20 due to rising and lowering of a lifter pin (not shown). A DC voltage is applied from the DC power supply 25 to the electrode film 21a, and thus the substrate 100 is electrostatically attracted to and held by the electrostatic chuck 21.

The gas supply source 15 outputs and supplies the processing gas into the processing chamber 10. The first high-frequency power supply 32 applies first high-frequency power to the stage 20. The second high-frequency power supply 34 applies second high-frequency power to the stage 20. This generates a plasma in the plasma processing space U. The generated plasma performs plasma processing on the substrate 100. The plasma processing may include the processing of step S12 and the processing of step S13 in the substrate processing method according to the above-described embodiment.

After the plasma processing, a DC voltage of positive or negative opposite to the polarity at the time of adsorption of the substrate 100 is applied from the DC power supply 25 to the electrode film 21a, thereby removing charges of the substrate 100. The processed substrate 100 is removed from the electrostatic chuck 21 due to rising and lowering of the lifter pin. When the gate valve G11 is opened, the substrate 100 is transferred out from the processing chamber 10.

An example of conditions for performing step S12 in the substrate processing apparatus 1 is as follows.
CF₄ gas: 50 sccm or more and 500 sccm or less
C₄F₈ gas: 3 sccm or more and 100 sccm or less
CHF₃ gas: 10 sccm or more and 300 sccm or less
O₂ gas: 3 sccm or more and 100 sccm or less
Pressure: 7 Pa or higher and 67 Pa or lower
High-frequency power HF: 500 W or higher and 3,000 W or lower
High-frequency power LF: 50 W or higher and 1,500 W or lower
Substrate temperature (first temperature): 20° C. or higher and 100° C. or lower
Period: 1 second or more and 10 seconds or less

Another example of the conditions for performing step S12 in the substrate processing apparatus 1 is as follows.
He gas: 200 sccm or more and 2,000 sccm or less
Pressure: 13 Pa or higher and 106 Pa or lower
High-frequency power HF: 0 W
High-frequency power LF: 500 W or more and 3,000 W or less
Substrate temperature (first temperature): 20° C. or higher and 100° C. or lower
Period: 1 second or more and 10 seconds or less

An example of conditions for performing step S13 in the substrate processing apparatus 1 is as follows.
Propylene gas: 10 sccm or more and 50 sccm or less
Helium gas: 300 sccm or more and 1,000 sccm or less
Hydrogen gas: 5 sccm or more and 50 sccm or less
Pressure: 0.3 Torr or higher and 2 Torr or lower
High-frequency power HF: 300 W or higher and 1,000 W or lower
High-frequency power LF: 0 W
Substrate temperature (first temperature): 200° C. or higher and 400° C. or lower

### Experimental Results

### (First Experiment)

In a first experiment, samples A1 to A3 shown below were prepared, and the cross section of each of samples A1 to A3 was observed.

### <Sample A1>

First, a substrate including a patterned silicon oxide film was provided. The silicon oxide film is an example of the base film. Next, the above-described step S12 was performed to hydrophobize the surface of the silicon oxide film including the tops. In step S12, a gas mixture of a CF₄ gas, a C₄F₈ gas, a CHF₃ gas, and an O₂ gas was used as the first gas. Next, the above-described step S13 was performed to selectively form a carbon film over the tops of the hydrophobized silicon oxide film. The thickness of the carbon film was 300 nm. The conditions for step S12 and step S13 were as follows.

Conditions for step S12
CF₄ gas: 200 sccm
C₄F₈ gas: 8 sccm
CHF₃ gas: 50 sccm
O₂ gas: 8 sccm
Pressure: 20 Pa (150 mTorr)
High-frequency power HF: 1,500 W
High-frequency power LF: 230 W
Substrate temperature (first temperature): 20° C.
Period: 2 seconds
   Conditions for step S13
Propylene gas: 11 sccm
Helium gas: 330 sccm
Hydrogen gas: 11 sccm
Pressure: 0.5 Torr
High-frequency power HF: 300 W
Substrate temperature (first temperature): 400° C.

### <Sample A2>

First, the same substrate as that of sample A1 was provided. Next, the above-described step S12 was performed to hydrophobize the surface of the silicon oxide film including the tops. In step S12, a helium gas was used as the first gas. Next, the above-described step S13 was performed to selectively form a carbon film over the tops of the hydrophobized silicon oxide film. The thickness of the carbon film was 300 nm. The conditions for step S12 were as follows. The conditions for step S13 were the same as those for step S13 in sample A1.

Conditions for step S12
He gas: 900 sccm
Pressure: 40 Pa (300 mTorr)
High-frequency power HF: 3,000 W
High-frequency power LF: 0 W
Substrate temperature (first temperature): 20° C.
Period: 5 seconds

### <Sample A3>

First, the same substrate as that of sample A1 was provided. Next, the above-described step S13 was performed without performing the above-described step S12 to selectively form a carbon film over the tops of the non-hydrophobized silicon oxide film. The thickness of the carbon film was 300 nm. The conditions for step S13 were the same as those for step S13 in sample A1.

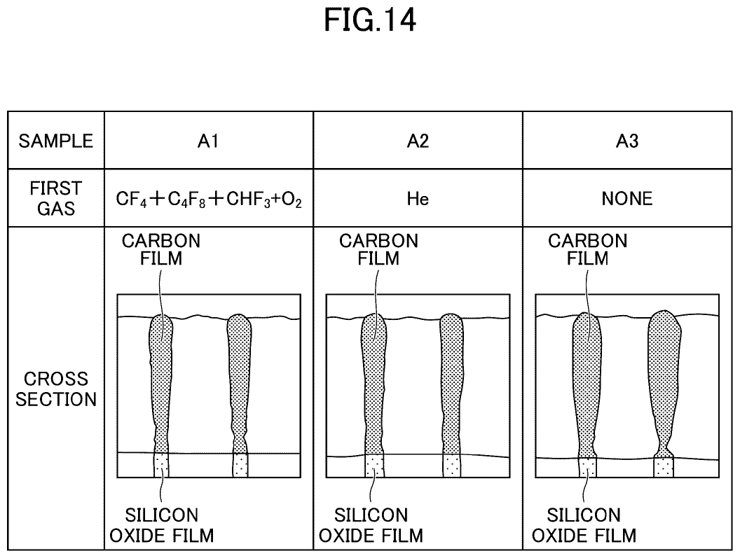

FIG. 14 is a table illustrating the results obtained by observing the cross sections of the carbon films. The cross sections of samples A1 to A3 were observed with a scanning electron microscope (SEM). FIG. 14 schematically illustrates SEM images of the cross sections of samples A1 to A3.

As illustrated in FIG. 14, substantially no defects were formed in the root portions of the carbon films in samples A1 and A2, while the root portions of the carbon films in sample A3 became thinned, resulting in the formation of defects. This result indicate that the formation of defects in the root portions of the carbon films could be reduced by selectively forming the carbon film over the tops of the silicon oxide film after the tops of the silicon oxide film was hydrophobized.

### (Second Experiment)

In a second experiment, samples B1 to B4 shown below were prepared, and the water contact angle of the surface of each of samples B1 to B4 was measured.

### <Sample B1>

First, a substrate including a patterned silicon oxide film was provided. The silicon oxide film is an example of the base film. Next, the above-described step S12 was performed on the provided substrate. In step S12, a gas mixture of a CF₄ gas, a C₄F₈ gas, a CHF₃ gas, and an O₂ gas was used as the first gas. The conditions for step S12 were the same as those for step S12 in sample A1 in the first experiment. The uppermost film of sample B1 was the silicon oxide film.

### <Sample B2>

First, the same substrate as that of sample B1 was provided. Next, the above-described step S12 was performed on the provided substrate. In step S12, a helium gas was used as the first gas. The conditions for step S12 were the same as those of step S12 in sample A2 in the first experiment. The uppermost film of sample B2 was the silicon oxide film.

### <Sample B3>

First, the same substrate as that of sample B1 was provided. In sample B3, the above-described step S12 was not performed on the provided substrate. The uppermost film of sample B3 was the silicon oxide film.

<sample B4>

First, the same substrate as that of sample B1 was provided. Next, the above-described step S13 was performed on the provided substrate to selectively form a carbon film over the tops of the silicon oxide film. The uppermost film of sample B4 was the carbon film.

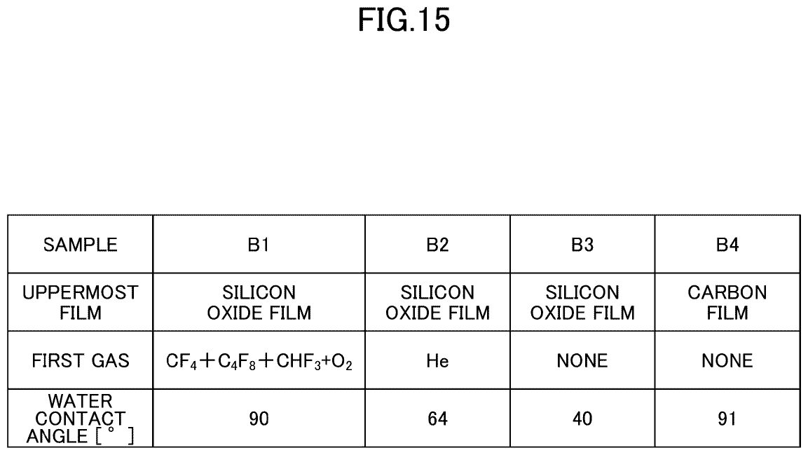

FIG. 15 is a table illustrating the results obtained by measuring the water contact angles of the sample surfaces. As illustrated in FIG. 15, the water contact angle of the surface of sample B1 was 90°, the water contact angle of the surface of sample B2 was 64°, the water contact angle of the surface of sample B3 was 40°, and the water contact angle of the surface of sample B4 was 91°. The greater the water contact angle, the higher the hydrophobicity of the surface of each sample. This result suggests the following.
(1) The water contact angle of the surface of sample B3 is smaller than the water contact angle of the surface of sample B4. In other words, the water contact angle of the surface of the silicon oxide film is smaller than the water contact angle of the surface of the carbon film. That is, the hydrophobicity of the surface of the silicon oxide film is lower than the hydrophobicity of the surface of the carbon film. This result indicates that the adhesion of the carbon film to the surface of the silicon oxide film is lower than the adhesion of the carbon film to the surface of the carbon film.
(2) The water contact angle of the surface of sample B1 and the water contact angle of the surface of sample B2 are larger than the water contact angle of sample B3. That is, the hydrophobicity of the surface of sample B1 and the hydrophobicity of the surface of sample B2 are higher than the hydrophobicity of the surface of sample B3. This result indicates that the adhesion of the carbon film to the surface of the silicon oxide film is improved by performing step S12 on the silicon oxide film using, as the first gas, a gas mixture of a CF₄ gas, a C₄F₈ gas, a CHF₃ gas, and an O₂ gas, or helium gas.
(3) The water contact angle of the surface of sample B1 is larger than the water contact angle of the surface of sample B2. That is, the hydrophobicity of the surface of sample B1 is higher than the hydrophobicity of the surface of sample B2. This result indicates that the adhesion of the carbon film to the surface of the silicon oxide film is especially improved by performing step S12 using, as the first gas, a gas mixture of a CF₄ gas, a C₄F₈ gas, a CHF₃ gas, and an O₂ gas.
(4) The water contact angle of the surface of sample B1 is substantially the same as the water contact angle of the surface of sample B4. That is, the hydrophobicity of the surface of sample B1 is substantially the same as the hydrophobicity of the surface of sample B4. This result indicates that the adhesion of the carbon film to the surface of the silicon oxide film is improved to the same extent as the adhesion of the carbon film to the surface of the carbon film by performing the above-described step S12 on the silicon oxide film.

According to the present disclosure, it is possible to reduce defects in the root portion of the carbon film when forming the carbon film over the top of a patterned base film.

The embodiments disclosed herein are exemplary in all respects and are non-limiting. Omissions, substitutions, or modifications are possible in the above embodiments in various ways without departing from the scope and intent of claims recited.

What is claimed is:

1. A substrate processing method, comprising:
providing a substrate including a patterned base film;
exposing the substrate to a plasma generated from a first gas containing a modifying gas, thereby hydrophobizing a surface of the patterned base film, the surface including a top of the patterned base film; and
exposing the substrate to a plasma generated from a second gas containing a raw material gas containing carbon and hydrogen, thereby selectively forming a carbon film over the hydrophobized top.

2. The substrate processing method according to claim 1, wherein
the modifying gas is a gas containing carbon and halogen.

3. The substrate processing method according to claim 2, wherein
the gas containing carbon and halogen is a fluorocarbon gas, a hydrofluorocarbon gas, or a combination of the fluorocarbon gas and the hydrofluorocarbon gas.

4. The substrate processing method according to claim 1, wherein
the modifying gas is an inert gas.

5. The substrate processing method according to claim 4, wherein
the inert gas is at least one of a helium gas, an argon gas, or a xenon gas.

6. The substrate processing method according to claim 1, wherein
in the hydrophobization of the surface of the patterned base film, a temperature of the substrate is maintained at a first temperature, and
in the formation of the carbon film, the temperature of the substrate is maintained at a second temperature that is higher than the first temperature.

7. The substrate processing method according to claim 1, wherein
the raw material gas is a hydrocarbon gas.

8. The substrate processing method according to claim 1, wherein
the patterned base film is a film containing silicon and oxygen.

9. The substrate processing method according to claim 8, wherein
the film containing silicon and oxygen is a silicon oxide film.

10. A substrate processing apparatus configured to perform processing on a substrate including a patterned base film, the substrate processing apparatus comprising:
a processor; and
a controller including circuitry configured to:
control the processor to expose the substrate to a plasma generated from a first gas containing a modifying gas, thereby hydrophobizing a surface of the patterned base film, the surface including a top of the patterned base film, and
control the processor to expose the substrate to a plasma generated from a second gas containing a raw material gas containing carbon and hydrogen, thereby selectively forming a carbon film over the hydrophobized top.

11. A substrate processing system configured to perform processing on a substrate including a patterned base film, the substrate processing system comprising:
a first processor;
a second processor; and
a controller including circuitry configured to:
control the first processor to expose the substrate to a plasma generated from a first gas containing a modifying gas, thereby hydrophobizing a surface of the patterned base film, the surface including a top of the patterned base film, and
control the second processor to expose the substrate to a plasma generated from a second gas containing a raw material gas containing carbon and hydrogen, thereby selectively forming a carbon film over the hydrophobized top.
